(19) United States
(12) Patent Application Publication
(10) Pub. No.: US 2011/0163408 A1
(43) Pub. Date: Jul. 7, 2011

(54) Schottky diode with low reverse leakage current and low forward voltage drop

(75) Inventors: Chiun-Yen Tung, Gangshan Township (TW); Kun-Hsien Chen, Kaohsiung City (TW); Kai-Ying Wang, Qiaotou Township (TW); Hung Ta Weng, Taipei City (TW); Yi-Chen Shen, Xizhou Township (TW)

(73) Assignee: PYNMAX TECHNOLOGY CO., LTD.

(21) Appl. No.: 12/655,698

(22) Filed: Jan. 6, 2010

(51) Int. Cl. H01L 29/872; H01L 29/06

(52) U.S. Cl. 257/476; 257/E29.338; 257/E29.008

(57) ABSTRACT

A Schottky diode structure with low reverse leakage current and low forward voltage drop has a first conductive material semiconductor substrate combined with a metal layer. An oxide layer is formed around the edge of the combined conductive material semiconductor substrate and the metal layer. A plurality of dot-shaped or line-shaped second conductive material regions are formed on the surface of the first conductive material semiconductor substrate connecting to the metal layer. The second conductive material regions form depletion regions in the first conductive material semiconductor substrate. The depletion regions can reduce the leakage current area of the Schottky diode, thereby reducing the reverse leakage current and the forward voltage drop. When the first conductive material is a P-type semiconductor, the second conductive material is an N-type semiconductor. When the first conductive material is an N-type semiconductor, the second conductive material is a P-type semiconductor.

### BACKGROUND OF THE INVENTION

1. Field of the Invention

The invention relates to a Schottky diode and, in particular, to a Schottky diode that can reduce the reverse leakage current and has a low forward voltage drop.

2. Description of Related Art

With reference to FIG. 8, the characteristic curve A in the drawing is depicted for a normal P-N diode. The other characteristic curve B is depicted for a normal Schottky diode. When the current imposed on the diode is a forward current, it is seen that the forward voltage drop of the P-N diode is larger than that of the Schottky diode when the forward current is small. However, as the forward current increases, the increased forward voltage per unit of the increased current for the P-N type diode is smaller than that of the Schottky diode. In the large forward current region, the forward voltage drop of the Schottky diode is similar to a resistor and increases rapidly. Therefore, its forward voltage drop is much larger than that of the P-N diode. This phenomenon becomes even more obvious if the barrier height is lower. As shown in FIG. 8, the forward voltage drops of the P-N diode and the Schottky diode cross each other. In comparison with the P-N diode, the Schottky diode has a lower forward conduction voltage and a shorter recovery time, and is thus suitable for high-speed operations and high-frequency rectification.

From another point of view, when a reverse voltage is imposed, the reverse leakage current of the Schottky diode is obviously larger than that of the P-N diode. This is a drawback of the Schottky diode. However, up to date, there is no Schottky diode that has the advantages of high-speed operations when the forward voltage drop produced under high or low current density and reduces the reverse leakage current under a reverse voltage.

To overcome the shortcomings, the present invention provides a Schottky diode with low reverse leakage current and low forward voltage drop to mitigate or obviate the aforementioned problems.

### SUMMARY OF THE INVENTION

When the current Schottky diode is imposed with a reverse voltage, it often has a large leakage current that limits its applications. Moreover, when imposed with a forward current load, it cannot have the advantage of relatively low forward voltage drop under both high and low current densities.

An objective of the invention is to provide a Schottky diode that keeps the advantages of high-speed operations and low forward voltage drop under a forward current and suppresses the leakage current under a reverse current.

To achieve the above objective, the Schottky diode comprises a first conductive material semiconductor substrate, an oxide layer and a metal layer.

The first conductive material semiconductor substrate is formed with an annular protection ring therein. The region enclosed by the protection ring is an active area. The active area is formed with a plurality of second conductive material regions in order to produce depletion regions inside the first conductive material semiconductor substrate.

The oxide layer covers the surface of the first conductive material semiconductor substrate. The metal layer covers the oxide layer and the active area of the first conductive material semiconductor substrate. The metal layer and the first conductive material semiconductor substrate form a Schottky contact. The second conductive material regions can be arranged in an array of dots or alternating dots.

In the above-mentioned structure, depletion regions form at the junction between the second conductive material regions and the first conductive material semiconductor substrate. The depletion regions can reduce the leakage current area when the Schottky diode operates under a reverse voltage. Therefore, it can reduce the reverse leakage current and the forward voltage drop.

### BRIEF DESCRIPTION OF THE DRAWINGS

FIG. 1 is a plan view of the first embodiment of the invention;

FIG. 2 is a cross-sectional view of the first embodiment of the invention;

FIG. 3 is a plan view of the second embodiment of the invention;

FIG. 4 is an enlarged plan view of a portion of the second embodiment of the invention;

FIG. 5 shows the voltage-current characteristic curve of the invention;

FIG. 6 is a plan view of the third embodiment of the invention;

FIG. 7 is a plan view of the fourth embodiment of the invention; and

FIG. 8 shows the voltage-current characteristic curves of a conventional P-N diode and a Schottky diode.

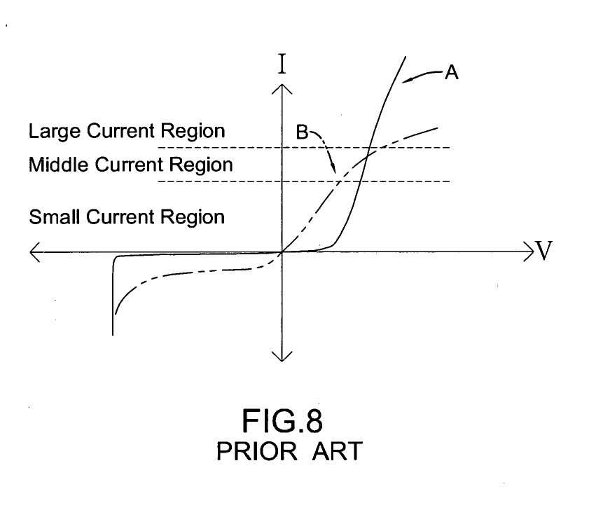

### DETAILED DESCRIPTION OF THE PREFERRED EMBODIMENT

The Schottky diode in accordance with the present invention contains semiconductor materials. The following description refers to them by “first conductive material” and “second conductive material.” If the first conductive material is a P-type semiconductor material, then the second conductive material is an N-type semiconductor material. If the first conductive material is an N-type semiconductor material, then the second conductive material is a P-type semiconductor material.

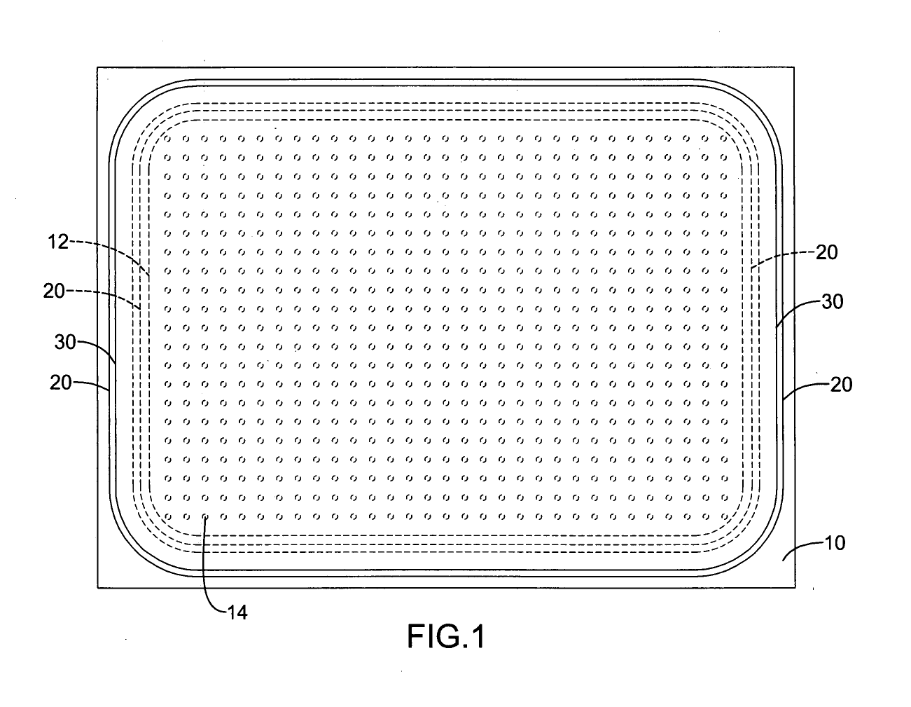

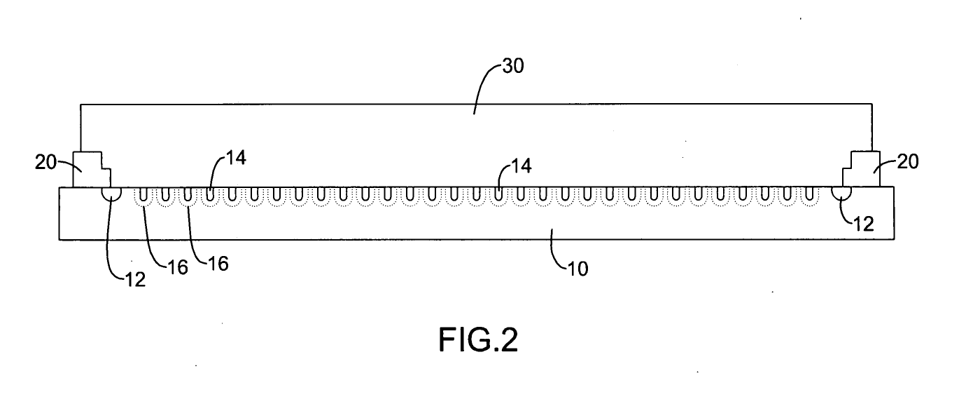

With reference to FIGS. 1 and 2, a first embodiment in accordance with the present invention comprises a first conductive material semiconductor substrate (10), an oxide layer (20), and a metal layer (30).

The first conductive material semiconductor substrate (10) is a substrate made of a first conductive material semiconductor material, such as an N-type substrate made of group-V elements As and P. The surrounding of the first conductive material semiconductor substrate (10) is formed with an annular protection ring (12). The annular protection ring (12) is made of the second conductive material and formed in the first conductive material semiconductor substrate (10). The area enclosed by the protection ring (12) is defined as an active area. Multiple second conductive material regions (14) are formed in the active area of the first conductive material semiconductor substrate (10). The second conductive material regions (14) can dot-shaped. In this embodiment, the dot-shaped second conductive material regions (14) are distributed in an array configuration. Also, the first conductive material is N-type, and the second conductive material is P-type.

The oxide layer (20) is an annular structure that covers the surface of the first conductive material semiconductor substrate (10). The oxide layer (20) covers part of the protection ring (12).

The metal layer (30) covers the oxide layer (20) and the active area of the first conductive material semiconductor substrate (10). A Schottky contact is formed between the metal layer (30) and the first conductive material semiconductor substrate (10).

The second conductive material regions (14) formed in the first conductive material semiconductor substrate (10) can be made into a P-type or N-type semiconductor by doping high-concentration group-III or group-V ions, respectively. Therefore, at the junction between the second conductive material regions (14) and the first conductive material semiconductor substrate (10), the combination of electrons and holes causes depletion regions (16) in the first conductive material semiconductor substrate (10). With the highly dense distribution of second conductive material regions (14), large depletion regions (16) can be formed in the first conductive material semiconductor substrate (10). The depletion regions (16) can reduce the leakage current area when the Schottky diode operates under a reverse voltage, thereby lowering the reverse leakage current.

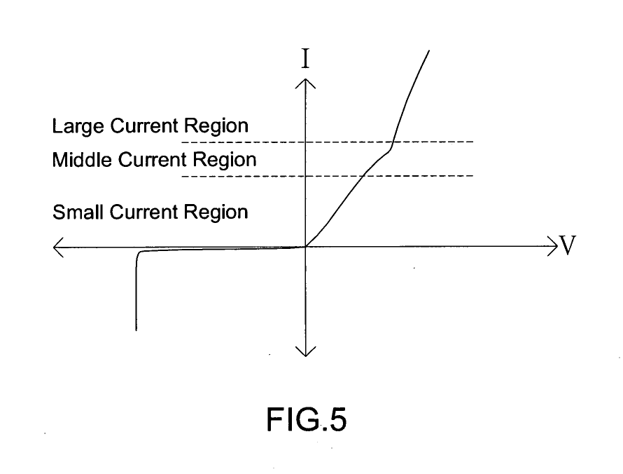

With reference to FIG. 5, a voltage-current characteristic curve of the Schottky diode in accordance with the present invention is shown. When a reverse current is imposed on the Schottky diode, the existence of the depletion region (16) obviously mitigates the leakage current thereof. When the imposed forward current is in the small current region, the Schottky diode has the advantage of low forward voltage drop. As the forward current increases and enters the large current region, the forward voltage drop of the Schottky diode does not rapidly rise in comparison with the conventional Schottky diodes. Therefore, the invention has relatively low forward voltage drop in both high and low current regions.

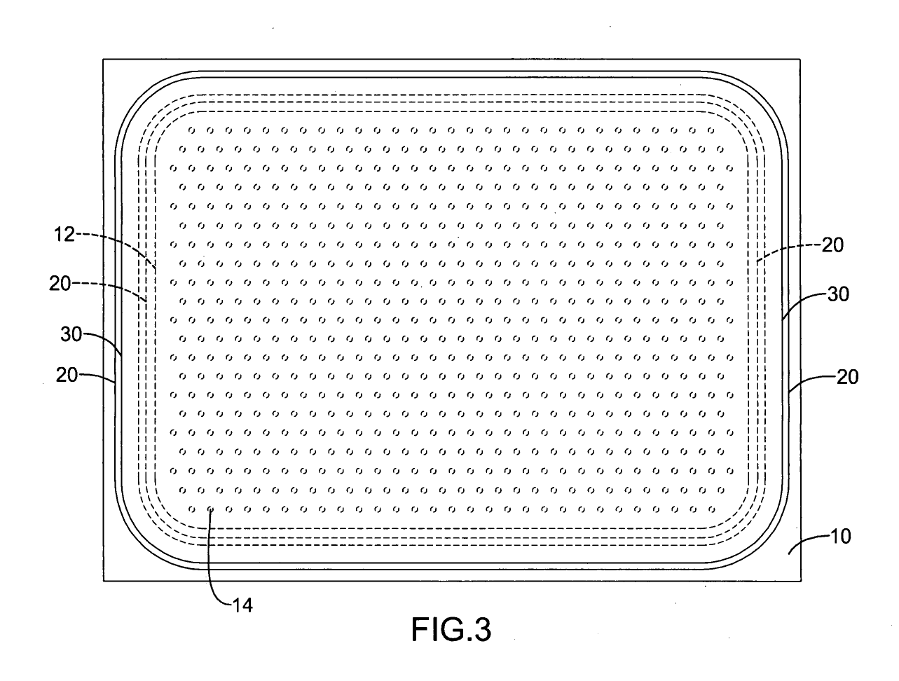

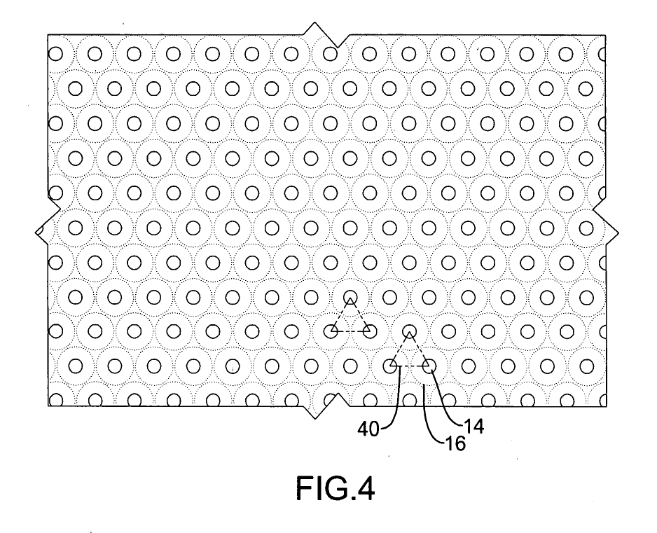

With reference to FIGS. 3 and 4 for a second embodiment of the invention, the second conductive material regions (14) are also dot-shaped and distributed in the first conductive material semiconductor substrate (10). However, they are not arranged in an array configuration, but alternating instead. That is, the second conductive material region (14) in each row is not in alignment with its most adjacent second conductive material regions (14) on the next row or previous row. Take any second conductive material region (14) along with its most adjacent two second conductive material regions (14), one obtains an equilateral triangle (40). The depletion regions (16) produced in such an arrangement cover a larger area and thus increase the suppression of reverse leakage current. This is because the gap between adjacent depletion regions (16) can be effectively reduced.

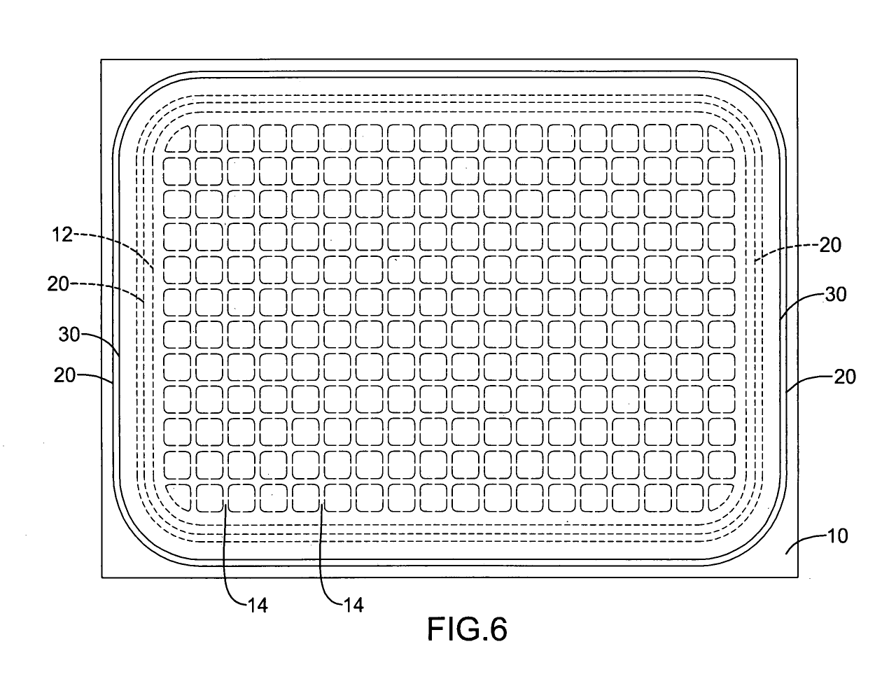

With reference to FIG. 6 for a third embodiment of the invention, in comparison with the above-mentioned embodiments, the second conductive material regions (14) are arranged in lines here. The lines are arranged in two parallel sets that cross each other to form a mesh. In this embodiment, the two sets of second conductive material regions (14) are perpendicular to each other.

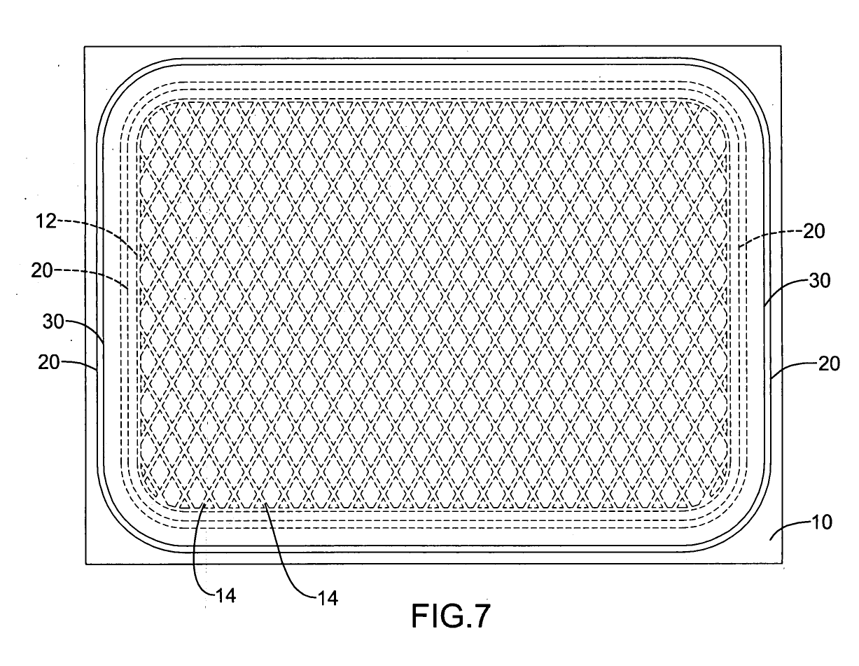

With reference to FIG. 7 for a plan view of a fourth embodiment it differs from the third embodiment in that the two sets of second conductive material regions (14) cross each other at an oblique angle. The region enclosed by the second conductive material regions (14) is an equilateral rhombus. The equilateral rhombus can be considered as the combination of two equilateral triangles. Therefore, the equilateral rhombus has two opposite 60-degree interior angles and two opposite 120-degree interior angles. Such an oblique arrangement can provide a depletion region covering a larger area.

In summary, the invention forms depletion regions at the junction between the first conductive material semiconductor substrate and the second conductive material regions. This improves the electronic properties of the Schottky diode so that it can be widely used in other fields.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A Schottky diode with low reverse leakage current and low forward voltage drop, comprising:
a first conductive material semiconductor substrate formed with an annular protection ring therein, an area enclosed by the protection ring being an active area formed with a plurality of second conductive material regions to form depletion regions in the first conductive material semiconductor substrate;
an oxide layer covering the surface of the first conductive material semiconductor substrate; and
a metal layer covering the oxide layer and the active area of the first conductive material semiconductor substrate, a Schottky contact thus formed between the metal layer and the first conductive material semiconductor substrate.

2. The Schottky diode as claimed in claim 1, wherein the second conductive material regions are dot-shaped.

3. The Schottky diode as claimed in claim 2, wherein the dot-shaped second conductive material regions are arranged in an array configuration.

4. The Schottky diode as claimed in claim 2, wherein the dot-shaped second conductive material regions are alternating.

5. The Schottky diode as claimed in claim 4, wherein any one of the second conductive material regions along with its most adjacent two second conductive material regions form an equilateral triangle.

6. The Schottky diode as claimed in claim 1, wherein the second conductive material regions are arranged in two sets of lines that cross each other to form a mesh.

7. The Schottky diode as claimed in claim 6, wherein the two sets of the second conductive material regions arranged in lines perpendicularly cross each other.

8. The Schottky diode as claimed in claim 6, wherein the two sets of the second conductive material regions arranged in lines cross each other at an oblique angle.

9. The Schottky diode as claimed in claim 8, wherein a region enclosed by the second conductive material regions crossing each other at the oblique angle is an equilateral rhombus.

10. The Schottky diode as claimed in claim 1, wherein the protection ring is made of the second conductive semiconductor material.

11. The Schottky diode as claimed in claim 1, wherein the first conductive material is an N-type semiconductor material and the second conductive material is a P-type semiconductor material.

12. The Schottky diode structure as claimed in claim 1, wherein the first conductive material is a P-type semiconductor material and the second conductive material is an N-type semiconductor material.
